(19) United States
(12) Patent Application Publication
(10) Pub. No.: US 2007/0139225 A1
(43) Pub. Date: Jun. 21, 2007

(54) Key input apparatus and method

(75) Inventor: Hyun-kyu Lee, Anyang-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 11/541,532

(22) Filed: Oct. 3, 2006

(30) Foreign Application Priority Data
Dec. 21, 2005 (KR) 2005-126931

(51) Int. Cl. H03M 11/00

(52) U.S. Cl. 341/22

(57) ABSTRACT

A key input apparatus and method includes a first key input unit, when any one of a plurality of keys of a first group is pressed, to output first data corresponding to the pressed key, a second key input unit, when any one of a plurality of keys of a second group is pressed, to output second data corresponding to the pressed key, and a key code generator to assign the first data and the second data to a certain row number and a certain column number, respectively, of a matrix and to generate a different key code corresponding to the row number and the column number of the matrix according to an order in which the first data and the second data are output, wherein the keys of the first group are different from the keys of the second group.

### CROSS-REFERENCE TO RELATED APPLICATIONS

This application claims priority under 35 U.S.C. §119(a) from Korean Patent Application No. 10-2005-0126931, filed on Dec. 21, 2005, in the Korean Intellectual Property Office, the disclosure of which is incorporated herein in its entirety by reference.

### BACKGROUND OF THE INVENTION

1. Field of the Invention

The present general inventive concept relates to a key input apparatus, and more particularly, to a key input apparatus and method.

2. Description of the Related Art

A portable device, such as a cellular phone, or a remote controller performs a number of operations with a small number of keys. According to a conventional portable device, a single operation is performed when a single key is pressed.

FIG. 1 is a block diagram illustrated a conventional key input circuit using a matrix scheme.

Referring to FIG. 1, small circles indicate a plurality of keys for inputting data. Each of these keys includes a switch and a diode. A rectangular shaped block in the left side indicates a micom (micro processor) with terminals P110˜P123. If any one of the keys which are listed is pressed, a signal input to the micom varies according to a location of the pressed key. The micom determines which key is pressed using a variation of this signal.

However, in such key input apparatuses, the number of keys must be increased when the number of operations to be performed increases. To address this problem, a method of determining an operation to be performed according to the number of key inputs by pressing the same key several times has been introduced. However, this method is also inconvenient since a user must memorize which function is performed when the user presses the same key the required number of times.

Thus, in a key input method according to the conventional key input apparatus, various functions cannot be performed by simply operating a small number of keys.

### SUMMARY OF THE INVENTION

The present general inventive concept provides a key input method for simply and conveniently generating a large number of key codes using a small number of keys.

The present invention also provides a key input apparatus of simply and conveniently generating a large number of key codes using a small number of keys

Additional aspects and advantages of the present general inventive concept will be set forth in part in the description which follows and, in part, will be obvious from the description, or may be learned by practice of the general inventive concept.

The foregoing and/or other aspects of the present general inventive concept may be achieved by providing a key input apparatus comprising a first key input unit, when any one of a plurality of keys of a first group is pressed, to output first data corresponding to the pressed key of the first group, a second key input unit, when any one of a plurality of keys of a second group is pressed, to output second data corresponding to the pressed key of the second group, and a key code generator to assign the first data and the second data to a certain row number and a certain column number, respectively, of a matrix and to generate a different key code corresponding to the row number and the column number of the matrix according to an order in which the first data and the second data are output, wherein the keys of the first group are different from the keys of the second group.

The foregoing and/or other aspects of the present general inventive concept may also be achieved by providing a key input apparatus comprising a first key input unit, when any one of a plurality of keys of a first group is pressed, to output first data corresponding to the pressed key of the first group, a second key input unit, when any one of a plurality of keys of a second group is pressed, to output second data corresponding to the pressed key of the second group, a third key input unit, when any one of a plurality of keys of a third group is pressed, outputting third data corresponding to the pressed key of the third group, and a key code generator to assign the first data, the second data, and the third data to a certain x-axis number, a certain y-axis number, and a certain z-axis number, respectively, of a matrix and to generate a key code corresponding to the x-axis number, the y-axis number, and the z-axis number of the matrix, wherein the keys of the first group, the keys of the second group, and the keys of the third group are different from each other.

The foregoing and/or other aspects of the present general inventive concept may also be achieved by providing a key input method comprising when any one of a plurality of keys of a first group is pressed, outputting first data corresponding to the pressed key of the first group using voltage division, when any one of a plurality of keys of a second group is pressed, outputting second data corresponding to the pressed key of the second group using voltage division, assigning the first data and the second data to a certain row number and a certain column number, respectively, of a matrix, and generating a different key code corresponding to the row number and the column number of the matrix according to an order in which the first data and the second data are output, wherein the keys of the first group are different from the keys of the second group.

The foregoing and/or other aspects of the present general inventive concept may also be achieved by providing a key input method comprising when any one of a plurality of keys of a first group is pressed, outputting first data corresponding to the pressed key using voltage division, when any one of a plurality of keys of a second group is pressed, outputting second data corresponding to the pressed key using voltage division, when any one of a plurality of keys of a third group is pressed, outputting third data corresponding to the pressed key using voltage division assigning the first data, the second data, and the third data to a certain x-axis number, a certain y-axis number, and a certain z-axis number, respectively, of a matrix, and generating a key code corresponding to the x-axis number, the y-axis number, and the z-axis number of the matrix, wherein the keys of the first group, the keys of the second group, and the keys of the third group are different from each other.

When any one of keys of the first group is pressed, data corresponding to the pressed key of the first group may be generated, and the generated data may be defined as the first data.

When any one of keys of the second group is pressed, data corresponding to the pressed key of the second group may be generated, and the generated data may be defined as the second data.

When any one of keys of the third group is pressed, data corresponding to the pressed key of the third group may be generated, and the generated data may be defined as the third data.

The generating of the key code may include preventing the generation of the key code and initializing the key code if any one of the first data, the second data, and the third data is output after a predetermined time passes after any one of the first data, the second data, and the third data is output.

The key code generator may generate a different key code according to a generation order of the first data and the second data.

The foregoing and/or other aspects of the present general inventive concept may also be achieved by providing a key input apparatus including a first key input unit having a first group of keys, a second key input unit having a second group of keys, and a key code generator to generate a key code corresponding to a combination of one of the first group of keys and one of the second group of keys.

The foregoing and/or other aspects of the present general inventive concept may also be achieved by providing a portable device including a body, a display device disposed on the body, and a key input apparatus disposed on the body, and having a first key input unit having a first group of keys, a second key input unit having a second group of keys, and a key code generator to generate a key code corresponding to a combination of one of the first group of keys and one of the second group of keys according to an order of the ones of the first group keys and the second group keys.

The foregoing and/or other aspects of the present general inventive concept may also be achieved by providing a computer readable recording medium containing computer readable codes to perform a key input method, the key input method including generating a key code corresponding to a combination of one of a first key input unit having a first group of keys and one of a second key input unit having a second group of keys according to an order of the ones of the first group keys and the second group keys.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram illustrating a conventional key input circuit using a matrix scheme;

FIG. 2 is a block diagram illustrating a key input apparatus according to an embodiment of the present general inventive concept;

FIG. 3 is a block diagram illustrating a key input apparatus according to another embodiment of the present general inventive concept;

FIG. 4 is a circuit diagram illustrating a key input apparatus according to an embodiment of the present general inventive concept;

FIG. 5 is a block diagram illustrating a key input apparatus according to another embodiment of the present general inventive concept;

FIG. 6 is a perspective view illustrating a portable device to which the key input apparatus of FIG. 3 is applied, according to an embodiment of the present general inventive concept;

FIG. 7 is a perspective view illustrating a portable device to which the key input apparatus of FIG. 5 is applied, according to an embodiment of the present general inventive concept;

FIG. 8 is a flowchart illustrating a key input method according to an embodiment of the present general inventive concept;

FIG. 9 is a flowchart illustrating a key input method according to another embodiment of the present general inventive concept; and

FIG. 10 is a flowchart illustrating a key input method according to another embodiment of the present general inventive concept.

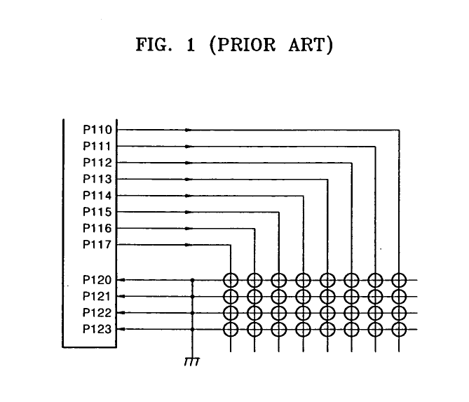

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

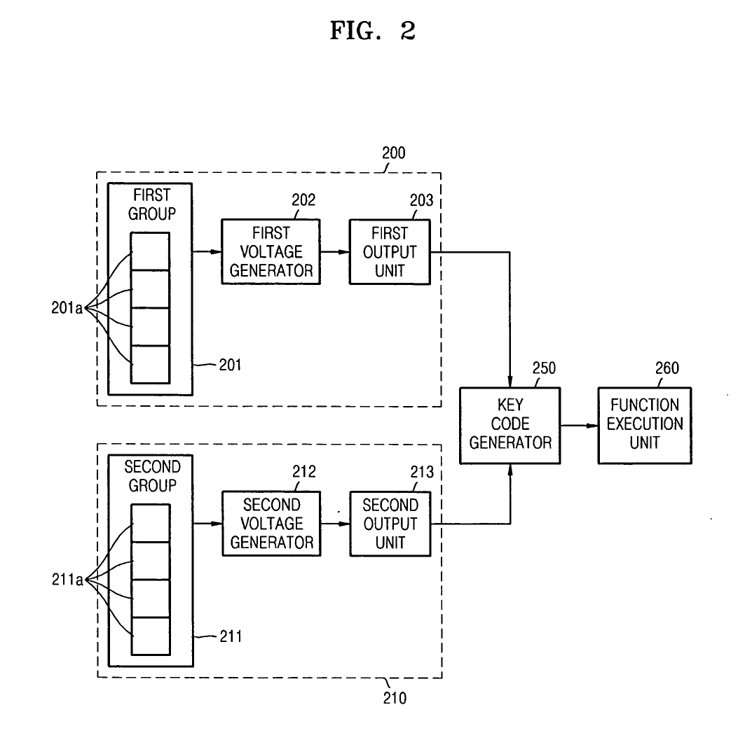

FIG. 2 is a block diagram illustrating a key input apparatus according to an embodiment of the present general inventive concept.

Referring to FIG. 2, the key input apparatus includes a first key input unit 200 and a second key input unit 210. When any one of a plurality of first keys 201a of a first group 201 is pressed, the first key input unit 200 outputs first data corresponding to the pressed key. The first key input unit 200 includes the first group 201, a first voltage generator 202, and a first output unit 203. The second key input unit 211 includes a plurality of second keys 211a.

The first group 201 and a second group 211 include the plurality of first and second keys 201a and 211a, respectively. The first keys 201a of the first group 201 are different from the second keys 211a of the second group 211. The number of the first keys 201a may be the same number as the second keys 211a.

The first voltage generator 202 generates a first voltage corresponding to a key signal input from the first group 201. The first voltage generator 202 may be a voltage divider including a plurality of different resistors connected to the respective first keys 201 a of the first group 201, and outputting a different voltage according to the pressed key using voltage division.

The first output unit 203 converts the first voltage to a digital voltage and outputs data corresponding to the digital voltage as the first data.

When any one of the second keys 211a of the second group 211 is pressed, the second key input unit 210 outputs second data corresponding to the pressed key. The second key input unit 210 includes the second group 211, a second voltage generator 212, and a second output unit 213.

The second group 211 is different and/or independent from the first group 201.

The second voltage generator 212 generates a second voltage corresponding to a key signal input from the second group 211. The second voltage generator 212 may be a voltage divider including a plurality of different resistors connected to the second keys 211a of the second group 211, and outputting a different voltage according to the pressed key using voltage division.

The second output unit 213 converts the second voltage to a digital voltage and outputs data corresponding to the digital voltage as the second data.

A key code generator 250 generates a key code by combining the first data and the second data. The key code generator 250 may assign the first data and the second data to a certain row number and a certain column number, respectively, of a matrix and generate the key code corresponding to the row number and the column number of the matrix.

Table 1 illustrates key codes corresponding to row numbers and column numbers of the matrix.

TABLE 1

| | Column number | Column number | Column number | Column number |
|---|---|---|---|---|
| | is 1 when | is 2 when | is 3 when | is 4 when |
| | second data is | second data is | second data is | second data is |
| | 1. | 2. | 3. | 4. |
| Row number is | 1 | 2 | 3 | 4 |
| 1 when first data | | | | |
| is 1. | | | | |
| Row number is | 5 | 6 | 7 | 8 |
| 2 when first data | | | | |
| is 2. | | | | |
| Row number is | 9 | 10 | 11 | 12 |
| 3 when first data | | | | |
| is 3. | | | | |
| Row number is | 13 | 14 | 15 | 16 |
| 4 when first data | | | | |
| is 4. | | | | |

In Table 1, the first data and the second data are assigned to the row numbers and the column numbers of the matrix, respectively. As illustrated in Table 1, when each of the number of the first keys 201a of the first group 201 and the number of the second keys 211a of the second group 211 is 4, the number of key codes that can be generated is 16.

The key code generator 250 may generate a different key code according to an output order of the first data and the second data. For example, the output order includes a first output order when the second data is output after the first data is output, and a second output order when the first data is output after the second data is output. Although the table 1 shows sixteen (16) key codes, when the output order of the first data and the second data is changed, the table 1 may show different sixteen key codes, and the number of key codes is 32. That is, a first set of key codes (or sixteen key codes) is generated in the table 1 when the first data is input before the second data, and a second set of key codes (or another sixteen key codes) is generated in the table 1 when the second date is input before the first data. In the table 1, numbers 1, 2 . . . 15, and 16 may represent corresponding operations to be performed according to the pressed keys of the first group 201 and the second group 211.

When any one of the first data and the second data is output after a predetermined time passes after any one of the first data and the second data is output, the key code generator 250 may not generate the key code but be initialized. That is, the previously generated first or second data is cancelled and another new set of the first and/or second data is required to generate the key codes according to a newly pressed key. The key code generator 250 is initialized to reduce an input error of a user.

A function execution unit 260 determines and performs a final operation according to the key code generated by the key code generator 250. To do this, a function execution unit 260 may comprise a function table in which a plurality of operations correspond to each combination of the key codes, for example, the numbers 1, 2 . . . 15, and 16. In a case that the number of the first keys 201a is different from the number of the second keys 211a, one or more extra keys 201a or 211a can be used to perform an operation which does not correspond to the combination of the table 1.

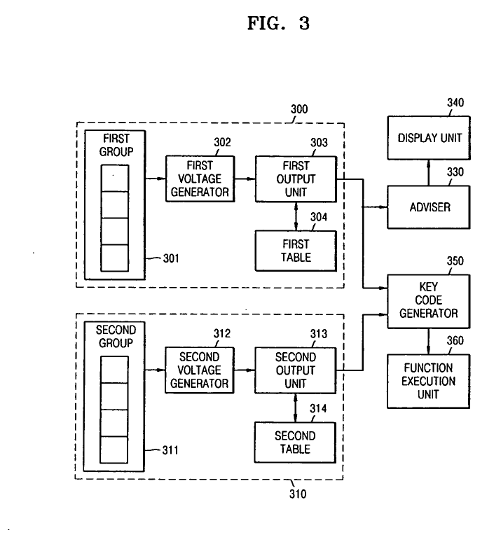

FIG. 3 is a block diagram illustrating a key input apparatus according to another embodiment of the present general inventive concept.

Referring to FIG. 3, the key input apparatus includes a first key input unit 300 having a first group 301, and a second key input unit 310 having a second group 311, and when any one of a plurality of keys of a first group 301 is pressed, a first key input unit 300 outputs first data corresponding to the pressed key. The first key input unit 300 includes the first group 301, a first voltage generator 302, a first output unit 303, and a first table 304.

The first group 301 and the second group 311 respectively also include the plurality of keys. The keys of the first group 301 are different from the keys of the second group 311.

The first voltage generator 302 generates a first voltage corresponding to a key signal input from the first group 301.

The first output unit 303 converts the first voltage to a digital voltage, searches the first table 304 for reference data corresponding to the digital voltage, and outputs the searched reference data corresponding to the digital voltage as the first data.

The first table 304 stores the reference data corresponding to a plurality of digital voltages generated by the first voltage generator 302.

When any one of the keys of the second group 311 is pressed, the second key input unit 310 outputs second data corresponding to the pressed key. The second key input unit 310 includes the second group 311, a second voltage generator 312, a second output unit 313, and a second table 314.

The second voltage generator 312 generates a second voltage corresponding to a key signal input from the second group 311.

The second output unit 313 converts the second voltage to a digital voltage, searches the second table 314 for reference data corresponding to the digital voltage, and outputs the searched reference data corresponding to the digital voltage as the second data.

The second table 314 stores the reference data corresponding to a plurality of digital voltages generated by the second voltage generator 312.

An adviser 330 generates key codes according to a combination of the generated first and second data. For example, when a generated key code is 1 in a case where the first data is 1 and the second data is 1, a generated key code is 2 in a case where the first data is 1 and the second data is 2, and a generated key code is 3 in a case where the first data is 1 and the second data is 3, if the first data is 1 generated by the first output unit 303, the adviser 330 respectively generates key codes 1, 2, and 3.

The adviser 330 may generate the key codes according to a generation order of the first data and the second data.

A display unit 340 visually displays the key codes generated by the adviser 330.

A key code generator 350 generates the key codes by combining the first data and the second data. The key code generator 350 may assign the first data and the second data to a certain row number and a certain column number of a matrix and generate the key code corresponding to the row number and the column number of the matrix.

The key code generator 350 may generate different key codes according to the generation order of the first data and the second data. That is, key codes generated when a key of the first group 301 is first pressed before a key of the second group 311 is pressed can be defined differently from key codes generated when a key of the second group 311 is first pressed before the key of the first group 301 is pressed. That is, if key codes are generated according to a key input order, the number of key codes generated can be doubled.

A function execution unit 360 determines and performs a final operation according to the key codes generated by the key code generator 350. To do this, the function execution unit 360 can comprise a function table in which a plurality of operations correspond to the respective key codes.

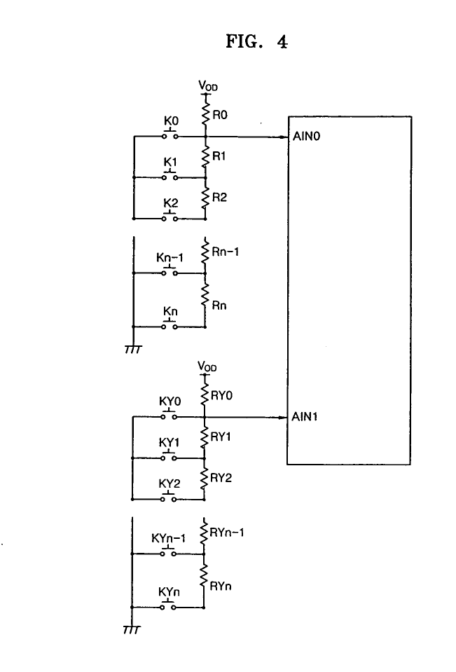

FIG. 4 is a circuit diagram illustrating a key input apparatus according to an embodiment of the present general inventive concept.

Referring to FIG. 4, a rectangular-shaped block in the right side indicates a micom (microprocessor) having terminals AIN0 and AIN1 includes the key code generator 250 or 350 and the function execution unit 260 or 360 of FIGS. 2 and 3. The micom may comprise the first table 304, the second table 314, and the adviser 330 of FIG. 3.

A first circuit comprising switches K0 . . . Kn and resistors R0 . . . Rn, which is located outside the micom, corresponds to the first group 201 or 301 and the first voltage generator 202 or 302, which are included in the first key input unit 200 or 300 illustrated in FIGS. 2 or 3. A second circuit comprising switches KY0 . . . KYn and resistors RY0 . . . RYn, which is located outside the micom and below the first circuit, corresponds to the second group 211 or 311 and the second voltage generator 212 or 312, which are included in the second key input unit 210 or 310 illustrated in FIGS. 2 or 3. Each of the first and second circuits including resistors is a type of a voltage divider.

Such a circuit comprising switches and resistors and outputting a different voltage according to a different key input is called an A/D terminal. The A/D terminal outputs a different voltage according to a different key input using a voltage division principle. Use of the A/D terminal simplifies a structure of such a circuit. Thus, the above circuit configuration can be applied to the key input apparatus of the current embodiment.

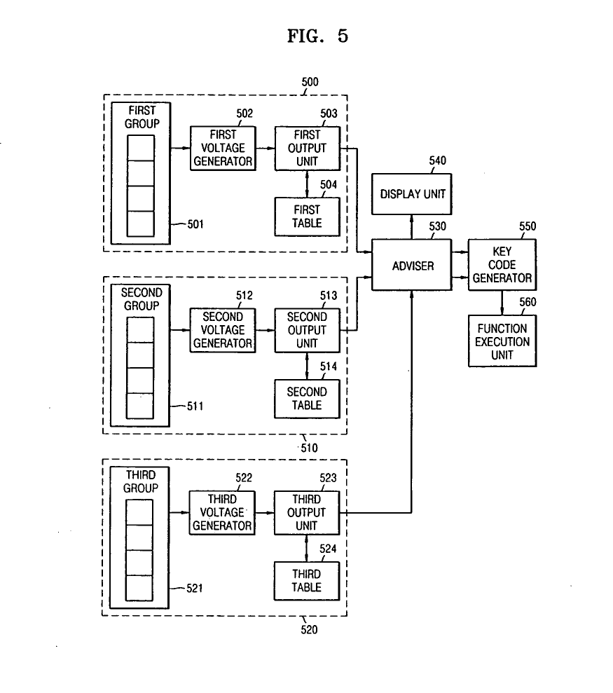

FIG. 5 is a block diagram illustrating a key input apparatus according to another embodiment of the present general inventive concept.

Referring to FIG. 5, the key input apparatus includes first, second, and third key input units 500, 510, and 520. When any one of a plurality of keys of a first group 501 is pressed, the first key input unit 500 outputs first data corresponding to the pressed key. The first key input unit 500 comprises the first group 501, a first voltage generator 502, a first output unit 503, and a first table 504.

The first group 501 and a second group 511 respectively include the plurality of keys. The keys of the first group 501 are different from the keys of the second group 511.

The first voltage generator 502 generates a first voltage corresponding to a key input from the first group 501.

The first output unit 503 converts the first voltage to a digital voltage, searches the first table 504 for data corresponding to the digital voltage, and outputs the searched data corresponding to the digital voltage as the first data.

The first table 504 stores data corresponding to a plurality of digital voltages generated by the first voltage generator 502.

When any one of the keys of the second group 511 is pressed, the second key input unit 510 outputs second data corresponding to the pressed key. The second key input unit 510 includes the second group 511, a second voltage generator 512, a second output unit 513, and a second table 514.

The second voltage generator 512 generates a second voltage corresponding to a key input from the second group 511.

The second output unit 513 converts the second voltage to a digital voltage, searches the second table 514 for data corresponding to the digital voltage, and outputs the searched data corresponding to the digital voltage as the second data.

The second table 514 stores data corresponding to a plurality of digital voltages generated by the second voltage generator 512.

When any one of a plurality of keys of a third group 521 is pressed, the third key input unit 520 outputs third data corresponding to the pressed key. The third key input unit 520 comprises the third group 521, a third voltage generator 522, a third output unit 523, and a third table 524.

The keys of the third group 521 are different from the keys of the first group 501 and second group 511.

The third voltage generator 522 generates a third voltage corresponding to a key input from the third group 521.

The third output unit 523 converts the third voltage to a digital voltage, searches the third table 524 for data corresponding to the digital voltage, and outputs the searched data corresponding to the digital voltage as the third data.

The third table 524 stores data corresponding to a plurality of digital voltages generated by the third voltage generator 522.

An adviser 530 generates key codes according to the first data when the first data is generated. In addition, the adviser 530 generates the key codes according to the first data and the second data when the first data and the second data are generated.

The adviser 530 may generate the key codes according to a generation order of the first data, the second data, and the third data, for example, the key codes are different according to a determination of which one of the first, second, and third data is first generated or which one of the keys of the first, second, and third groups 501, 511, and 521 is first pressed.

A display unit 540 visually displays the key codes generated by the adviser 530. It is possible that the selected key code can be highlighted among the plurality of key codes on the display 540.

A key code generator 550 generates a key code by combining the first data, the second data, and the third data. The key code generator 550 may assign the first data, the second data, and the third data to a certain x-axis number, a certain y-axis number, and a certain z-axis number of a matrix, respectively, and generate the key code corresponding to the x-axis number, the y-axis number, and the z-axis number of the matrix.

The key code generator 550 may generate a different key code according to the order in which the first data, the second data, and the third data are generated. That is, first key codes that can be generated when a key of the first group 501 is first pressed, second key codes that can be generated when a key of the second group 511 is first pressed, and third key codes that can be generated when a key of the third group 521 is first pressed can be defined differently from each other. That is, if the key codes are generated according to a key input order, the number of key codes generated can be enlarged by a multiple of six.

When any one of the first data, the second data, and the third data is output after a predetermined time passes after any one of the first data, the second data, and the third data is output, the key code generator 550 may not generate a key code but be initialized. The key code generator 550 is initialized to reduce/eliminate user input errors.

A function execution unit 560 determines and performs a final operation according to the key code generated by the key code generator 550. To do this, a function execution unit 560 may comprise a function table included therein, in which a plurality of operations correspond to the respective key codes.

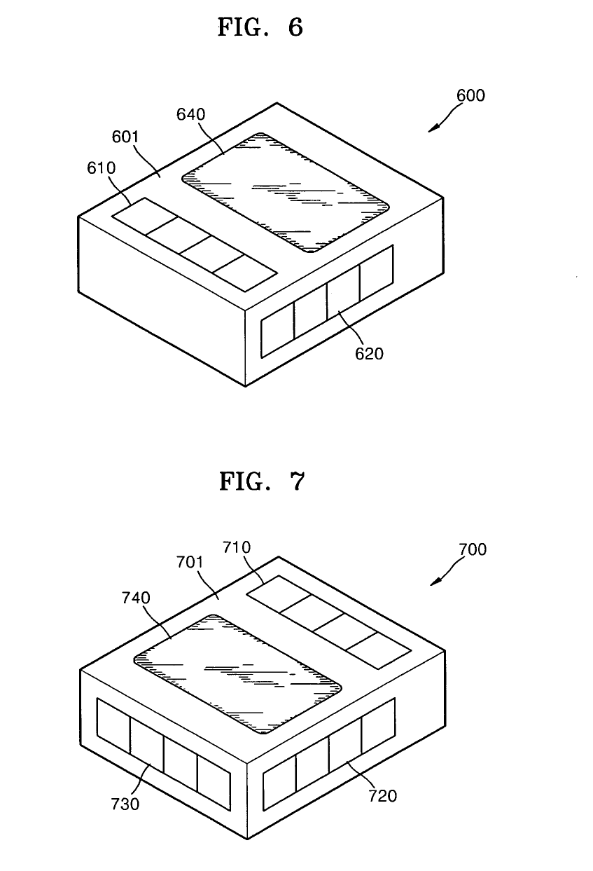

FIG. 6 is a perspective view illustrating a portable device 600 to which the key input apparatus of FIG. 3 is applied, according to an embodiment of the present invention.

Referring to FIG. 6, the portable device 600 comprises a body (frame) 601 and a number of keys, for example, a total of eight keys, including keys of a first group 610 and separate keys of a second group 620. If a user presses a key of the first group 610 and a key of the second group 620 using different fingers, for example only the thumb and the index finger, respectively, the portable device 600 can generate 16 or 32 key codes. The first group 610 and the second group 620 may be disposed on a same side or different sides of the body 601. When the first group 610 and the second group 620 are disposed on the same side, the first group 610 is disposed on a first location of the same side, and the second group 620 is disposed on a second location of the same side. The portable device 600 may include a display 640 disposed on the body 601 to display key codes generated according to one or more combinations of the keys of the first group 610 and the second group 620. The body 601 of the portable device may have a terminal unit (wireless terminal unit) to communicate with an external device to exchange data, and also have a function unit (for example, the function execution unit 260 of FIG. 2) to perform an operation corresponding to the key code selected among the keys of the first and second groups 610 and 620. It is possible that the body communicates with the external device through the terminal unit to control the external device to perform the operation corresponding to the key code selected by the keys of the first and second groups 610 and 620.

FIG. 7 is a perspective view illustrating a portable device 700 to which the key input apparatus of FIG. 5 is applied, according to an embodiment of the present general inventive concept.

Referring to FIG. 7, the portable device 700 comprises a body (frame) 701 and a number of keys, for example, a total of twelve keys, including keys of a first group 710, separate keys of a second group 720, and separate keys of a third group 730. If a user presses a key of the first group 710, a key of the second group 720, and a key of the third group 730 using different fingers, for example, only the thumb and the index finger of one hand, and the thumb of the other hand, respectively, the portable device 700 can generate 64 or 384 key codes. The portable device 700 may include a display 740 to display the key codes corresponding to the keys.

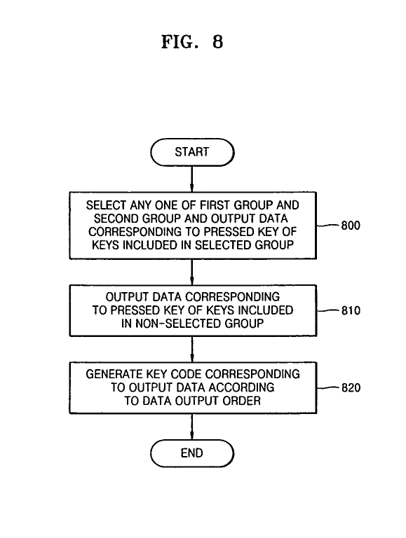

FIG. 8 is a flowchart illustrating a key input method according to an embodiment of the present general inventive concept.

Referring to FIG. 8, in operation 800, any one of a first group and a second group, each including a plurality of keys, is selected, and if a certain key included in the selected group is pressed, data corresponding to the pressed key is output. Each of the first group and the second group is a set of separate keys. The data output process in operation 800 may include outputting a different voltage according to a key input using voltage division, and generating first data in response to the output voltage.

In operation 810, if a certain key included in the non-selected group (remaining group) is pressed, data corresponding to the pressed key is output. The data output process in operation 810 may include outputting a different voltage according to a key input using voltage division, and generating second data in response to the output voltage.

If a certain key included in the first group is pressed, data corresponding to the pressed key may be generated, and this data may be defined as the first data.

If a certain key included in the second group is pressed, data corresponding to the pressed key may be generated, and this data may be defined as the second data.

In operation 820, a key code corresponding to the output data may be generated according to a data output order. If the output order of the first data and the second data (operations 800 and 810) is changed, a different key code may be generated according to the changed output order.

In the generation of the key code (operation 820), when any one of the first data and the second data is output after a predetermined time passes after any one of the first data and the second data is output, the key code may not be generated but be initialized to reduce/eliminate user input errors.

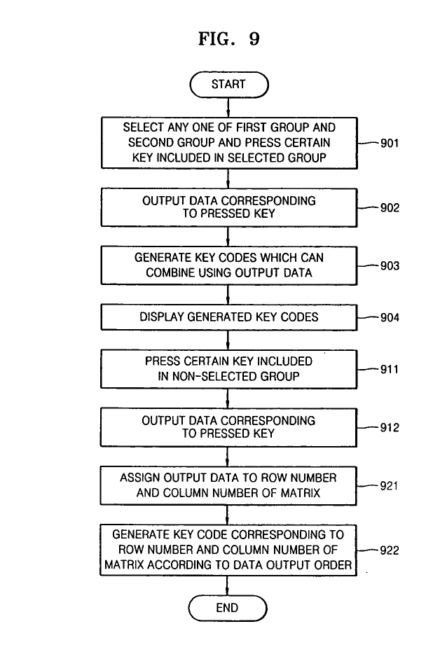

FIG. 9 is a flowchart illustrating a key input method according to another embodiment of the present general inventive concept.

Referring to FIG. 9, in operation 901, any one of a first group and a second group is selected, and a certain key included in the selected group is pressed.

Then, in operation 902, data corresponding to the pressed key in the selected group is output.

In operation 903, if data corresponding to the pressed key is output, key codes to be combined are generated using the output data.

In operation 904, the key codes are visually displayed.

In operation 911, if the key codes are visually displayed, a certain key included in the non-selected group (remaining group) is pressed.

Then, in operation 912, data corresponding to the pressed key in the non-selected group is output.

In operation 921, if all data is output, the output data is assigned to a row number and a column number of a matrix.

The last, in operation 922, a key code corresponding to the row number and the column number of the matrix is generated according to a data output order.

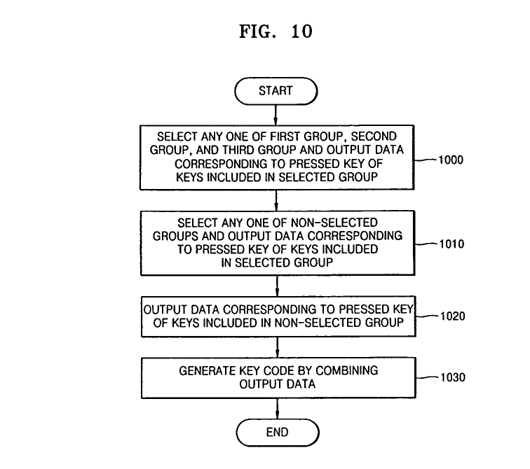

FIG. 10 is a flowchart illustrating a key input method according to another embodiment of the present general inventive concept.

Referring to FIG. 10, in operation 1000, any one of a first group, a second group, and a third group, each including a plurality of keys, is selected, and if a certain key included in the selected group is pressed, data corresponding to the pressed key in the selected group is output.

In operation 1010, any one of the non-selected groups is selected, and if a certain key included in the selected group is pressed, data corresponding to the pressed key is output.

Then, in operation 1020, if a certain key included in the non-selected group is pressed, data corresponding to the pressed key is output.

The last, in operation 1030, a key code is generated by combining all the output data. If the data output order is changed, a different key code may be generated.

If a certain key included in the first group is pressed, data corresponding to the pressed key in the first group may be generated, and this data may be defined as the first data.

If a certain key included in the second group is pressed, data corresponding to the pressed key in the second group may be generated, and this data may be defined as the second data.

If a certain key included in the third group is pressed, data corresponding to the pressed key in the third group may be generated, and this data may be defined as the third data.

In the generation of a key code (operation 1020), when any one of the first data, the second data, and the third data is output after a predetermined time passes after any one of the first data, the second data, and the third data is output, a key code may not be generated but be initialized to reduce/eliminate user input errors.

As described above, according to embodiments of the present general inventive concept, by simply and conveniently generating a large number of key codes using a small number of keys, a structure of a key input apparatus is simplified, an area occupied by the key input apparatus is minimized, a user-friendly key input apparatus is provided.

The present general inventive concept can be realized as software code to perform the above-described methods. When the present general inventive concept is realized as software code, components of the present invention are embodied as code segments for executing required operations. A program or the code segments can be stored in a processor readable recording medium (or a computer readable recording medium and transmitted as computer data signals combined with a carrier using a transmission medium or a communication network.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A key input apparatus comprising:
a first key input unit, when any one of a plurality of keys of a first group is pressed, to output first data corresponding to the pressed key of the first group;
a second key input unit, when any one of a plurality of keys of a second group is pressed, to output second data corresponding to the pressed key of the second group; and
a key code generator to assign the first data and the second data to a certain row number and a certain column number, respectively, of a matrix, and to generate a different key code corresponding to the row number and the column number of the matrix according to the order in which the first data and the second data are output,
wherein the keys of the first group are different from the keys of the second group.

2. The key input apparatus of claim 1, further comprising:
an adviser to generate key codes to be combined using the output first data; and
a display unit to visually display the key codes generated by the adviser.

3. The key input apparatus of claim 1, further comprising:
a first table to store data corresponding to a plurality of digital voltages,
wherein the first key input unit comprises:
a first voltage generator to generate a first voltage corresponding to the pressed key of the first group; and
a first output unit to convert the generated first voltage to a digital voltage, to search the first table for data corresponding to the converted digital voltage, and to output the searched data corresponding to the converted digital voltage as the first data.

4. The key input apparatus of claim 3, wherein the first voltage generator comprises a voltage divider having a plurality of resistors connected to the keys of the first group to output the different voltage according to the pressed key using voltage division.

5. The key input apparatus of claim 3, further comprising:
a second table to store data corresponding to a plurality of digital voltages,
wherein the second key input unit comprises:
a second voltage generator to generate a second voltage corresponding to the pressed key of the second group; and
a second output unit to convert the generated second voltage to a digital voltage, to search the second table for data corresponding to the converted digital voltage, and to output the searched data corresponding to the converted digital voltage as the second data.

6. The key input apparatus of claim 5, wherein the second voltage generator comprises a second voltage divider having a plurality of second resistors connected to the keys of the second group to output a different voltage according to the pressed key using second voltage division.

7. The key input apparatus of claim 1, wherein the key code generator does not generate the key code but initialize the first and second data if any one of the first data and the second data is output after a predetermined time passes after any one of the first data and the second data is output.

8. A key input apparatus comprising:
a first key input unit, when any one of a plurality of keys of a first group is pressed, to output first data corresponding to the pressed key of the first group;
a second key input unit, when any one of a plurality of keys of a second group is pressed, to output second data corresponding to the pressed key of the second group;
a third key input unit, when any one of a plurality of keys of a third group is pressed, to output third data corresponding to the pressed key of the third group; and
a key code generator to assign the first data, the second data, and the third data to a certain x-axis number, a certain y-axis number, and a certain z-axis number, respectively, of a matrix, and to generate a key code corresponding to the x-axis number, the y-axis number, and the z-axis number of the matrix,
wherein the keys of the first group, the keys of the second group, and the keys of the third group are different from each other.

9. The key input apparatus of claim 8, wherein the key code generator generates a different key code corresponding to the x-axis number, the y-axis number, and the z-axis number of the matrix according to an order in which the first data, the second data, and the third data are output.

10. The key input apparatus of claim 8, wherein the key code generator does not generate the key code but initialize the first and second data if any one of the first data, the second data, and the third data is output after a predetermined time passes after any one of the first data, the second data, and the third data is output.

11. A key input method comprising:
when any one of a plurality of keys of a first group is pressed, outputting first data corresponding to the pressed key of the first group using voltage division, and when any one of a plurality of keys of a second group is pressed, outputting second data corresponding to the pressed key of the second group using voltage division; and
assigning the first data and the second data to a certain row number and a certain column number, respectively, of a matrix, and generating a key code corresponding to the row number and the column number of the matrix according to an order in which the first data and the second data are output,
wherein the keys of the first group are different from the keys of the second group.

12. The key input method of claim 11, wherein the outputting of the first data comprises:
generating key codes to be combined into the key code using the output first data; and
visually displaying the generated key codes.

13. The key input method of claim 11, wherein the generating of the key code corresponding to the row number and the column number of the matrix comprises preventing the generation of the key code if any one of the first data and the second data is output after a predetermined time passes after any one of the first data and the second data is output, and performing initialization of the first and second data.

14. A key input method comprising:
when any one of a plurality of keys of a first group is pressed, outputting first data corresponding to the pressed key using voltage division, and when any one of a plurality of keys of a second group is pressed, outputting second data corresponding to the pressed key using voltage division, and when any one of a plurality of keys of a third group is pressed, outputting third data corresponding to the pressed key using voltage division; and
assigning the first data, the second data, and the third data to a certain x-axis number, a certain y-axis number, and a certain z-axis number, respectively, of a matrix, and generating a key code corresponding to the x-axis number, the y-axis number, and the z-axis number of the matrix,
wherein the keys of the first group, the keys of the second group, and the keys of the third group are different from each other.

15. The key input method of claim 14, wherein the generating of the key code corresponding to the x-axis number, the y-axis number, and the z-axis number of the matrix comprises preventing the generation of the key code if any one of the first data, the second data, and the third data is output after a predetermined time passes after any one of the first data, the second data, and the third data is output, and performing initialization of the first and second data.

16. A key input apparatus comprising:
a first key input unit having a first group of keys;
a second key input unit having a second group of keys; and
a key code generator to generate a key code corresponding to a combination of one of the first group of keys and one of the second group of keys.

17. The key input apparatus of claim 16, wherein the key code generator generates a plurality of key codes including the key code to correspond to combinations of the respective first group keys and the respective second group keys.

18. The key input apparatus of claim 17, further comprising:
a display,
wherein the plurality of key codes are displayed on the display when at least one of the first group keys and the second group keys is selected.

19. The key input apparatus of claim 17, further comprising:
a display,
wherein the plurality of key codes comprises a first plurality of key codes and a second plurality of key codes, and the display displays the first plurality of key codes when one of the first group keys is selected before the second group keys and displays the second plurality of key codes when one of the second group keys is selected before the first group keys.

20. The key input apparatus of claim 17, wherein the display displays a table representing the plurality of key codes.

21. The key input apparatus of claim 20, wherein the display highlights the key code among the plurality of key codes in the table.

22. The key input apparatus of claim 16, wherein the key code generator generates another key code according to an order of the ones of the first group keys and the second group keys.

23. The key input apparatus of claim 22, wherein the order comprises a first order when the one of the first group keys is selected before the one of the second group keys, and a second order when the one of the second group keys is selected before the one of the first group keys, and the key code generator generates the key code according to the first order, and the another key code according to the second order.

24. The key input apparatus of claim 16, wherein the key code generator generates the key code according to an order of the ones of the first and second groups.

25. The key input apparatus of claim 16, wherein the key code generator generates the key code when the ones of the first group keys and the second group keys are selected within a predetermined period of time.

26. The key input apparatus of claim 16, wherein the key code generator does not generate the key code when the ones of the first group keys and the second group keys are not selected within a predetermined period of time.

27. The key input apparatus of claim 16, wherein the key code generator generates a new key code according to a new combination of one of the first group keys and one of the second group keys when the ones of the first group keys and the second group keys are not selected within a predetermined period of time.

28. The key input apparatus of claim 16, wherein the number of the first group keys is the same as the number of the second group keys.

29. The key input apparatus of claim 16, wherein the first group keys are different from the second group keys.

30. A portable device comprising:
a body;
a display device disposed on the body; and
a key input apparatus disposed on the body, and having a first key input unit having a first group of keys, a second key input unit having a second group of keys, and a key code generator to generate a key code corresponding to a combination of one of the first group of keys and one of the second group of keys according to an order of the ones of the first group keys and the second group keys.

31. The portable device of claim 30, wherein the first key input unit and the second key input unit are spaced-apart from each other and disposed within a distance where two fingers of a user can reach corresponding ones of the first key input unit and the second key input unit.

32. The portable device of claim 30, wherein the two fingers comprise a thumb and an index finger of the user.

33. The portable device of claim 30, wherein the two fingers comprise a finger of one hand and a finger of the other hand of the user.

34. The portable device of claim 30, wherein the first key input unit is disposed on a first position of the body and the second key input unit is disposed on a second position of the body.

35. The portable device of claim 34, wherein the first position and the second position are disposed within a distance where two fingers of a user can reach the respective first and second key input unit.

36. The portable device of claim 34, wherein the display is disposed between the first position and the second position.

37. The portable device of claim 30, wherein the body comprises a first side and a second side different from the first side, and the first key input init is disposed on the first side of the body and the second key input unit is disposed on the second side of the body.

38. The portable device of claim 37, wherein the display is disposed on one of the first and second sides of the body.

39. The portable device of claim 30, wherein the key code generator generates a plurality of key codes including the key code to correspond to combinations of the respective first group keys and the respective second group keys, and the display displays the generated plurality of key codes.

40. The portable device of claim 30, wherein the body comprises a function unit to perform an operation of the generated key code.

41. A computer readable recording medium containing computer readable codes to perform a key input method, the key input method comprising:
generating a key code corresponding to a combination of one of a first key input unit having a first group of keys and one of a second key input unit having a second group of keys according to an order of the ones of the first key input unit and the second key input unit.
